(19) United States
(12) Patent Application Publication
(10) Pub. No.: US 2015/0201507 A1
(43) Pub. Date: Jul. 16, 2015

(54) HOUSING AND METHOD FOR MANUFACTURING HOUSING

(71) Applicant: HON HAI PRECISION INDUSTRY CO., LTD., New Taipei (TW)

(72) Inventor: SHAO-HAN CHANG, New Taipei (TW)

(21) Appl. No.: 14/498,073

(22) Filed: Sep. 26, 2014

(30) Foreign Application Priority Data
Jan. 11, 2014 (CN) 2014100118145

(51) Int. Cl. H05K 5/00; H05K 5/02; H05K 5/04

(52) U.S. Cl. CPC H05K 5/0086; H05K 5/04; H05K 5/003; H05K 5/0247; H05K 5/0213

(57) ABSTRACT

A housing for electronic device includes a plurality of sound-enhancing holes, an inner surface, and an outer surface opposite to the inner surface. Each sound hole comprises an entrance located on the inner surface, and an exit located on the outer surface. A diameter of a sound hole increases from the center of the each sound hole to the exit. The present disclosure also provides a method for manufacturing the housing.

### FIELD

The subject matter herein generally relates to a housing for electronic device and a method for manufacturing the housing.

### BACKGROUND

Recently, electronic products have gradually become light, chic, and miniaturized, and people can use the miniaturized electronic products, such as a radio or a walkman, at anytime and anywhere. Moreover, the personal digital product, such as MP3 player, cell phones, personal digital assistants (PDAs), and notebooks, has increasingly become popular, and thus being indispensable in the daily life. In addition, the cell phone integrated with functions of both radio and MP3 playback has emerged.

No matter the kind of electronic product, an user cannot listen to the sound provided by the electronic product without a sound hole. Moreover, a good sound hole also provides a better experience.

### BRIEF DESCRIPTION OF THE DRAWINGS

Implementations of the present technology will now be described, by way of example only, with reference to the attached figures.

FIG. 1 is a cross-sectional view of a first embodiment of a housing for electronic device.

FIG. 2 is a view of circled portion II in FIG. 1.

FIG. 3 is a perspective view of the first embodiment of a processing device.

FIG. 4 is a cross-sectional view of the first embodiment of the housing and the processing device.

FIG. 5 is another cross-sectional view of the first embodiment of the housing and the processing device.

FIG. 6 is a view of circled portion VI of FIG. 5.

FIG. 7 is a cross-sectional view of a second embodiment of an housing for electronic device.

FIG. 8 is a perspective view of the processing device of FIG. 7.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein.

Several definitions that apply throughout this disclosure will now be presented.

The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising”, when utilized, means “including, but not necessarily limited to”; it specifically indicates open-ended inclusion or membership in the so-described combination, group, series and the like.

The present disclosure describes a housing for electronic device and a method for manufacturing the housing.

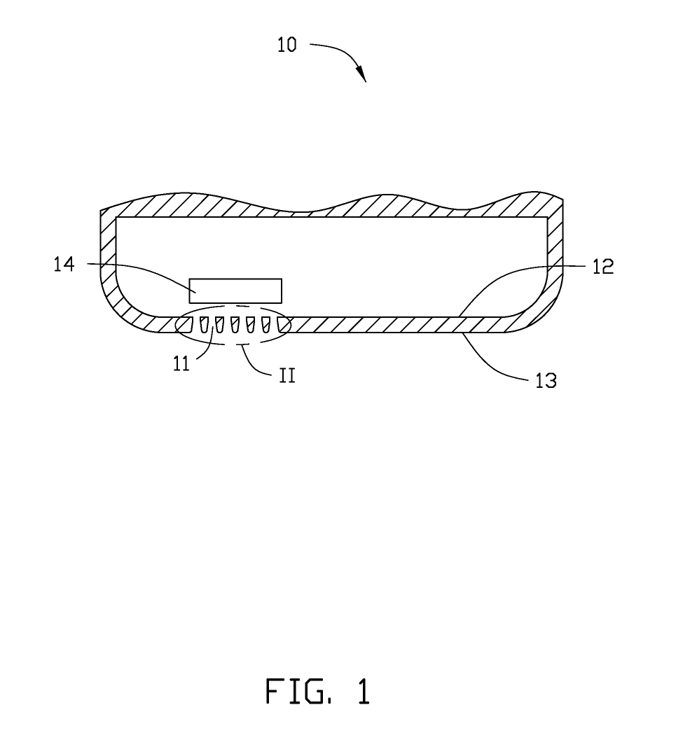

FIG. 1 illustrates a first embodiment of a housing 10 for electronic device. The housing 10 can include a plurality of sound holes 11 defined on the housing 10, an inner surface 12, and an outer surface 13 opposite to the inner surface 12. The plurality of sound holes 11 can be evenly distributed on the housing 10. A loudspeaker 14 can be received in the housing 10, adjacent to the plurality of sound holes 11. In the illustrated embodiment, the housing 10 can be made of a metal. In other embodiments, the housing 10 can be made of a plastic material.

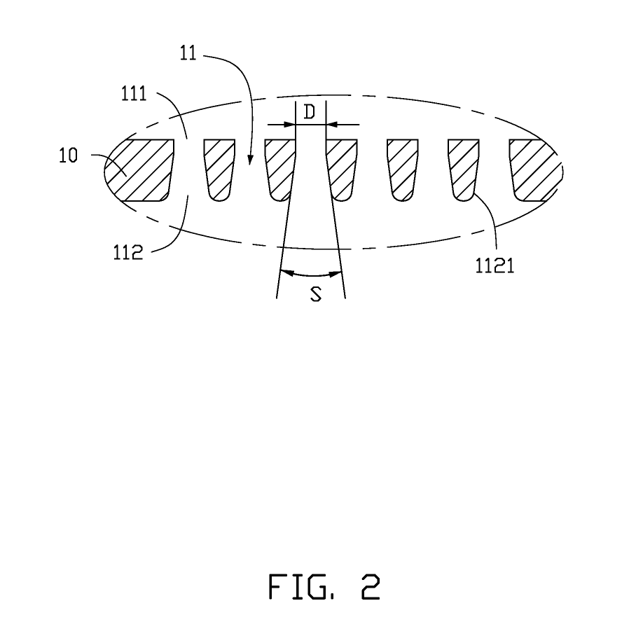

Referring to FIG. 2, each sound hole 11 includes an entrance 111 located on the inner surface 12, and an exit 112 located on the outer surface 13 (see FIG. 1). A cross-section of each sound hole 11 is substantially circular, and a diameter of each sound hole 11 gradually increases from the entrance 111 to the exit 112. An angle of the cone of each sound hole 11 can be defined as S, and the angle of the cone S can be greater than 5 degrees and less than 40 degrees. A diameter of the entrance 111 can be defined as D, and the diameter D can be greater than 0.5 millimeters and less than 1.5 millimeters. In other embodiments, the cross-section of each sound hole 11 can be substantially polygonal.

The exit 112 can define a rounded structure 1121, and the rounded structure 1121 is trumpet-shaped, so a tone quality of an electronic device with the housing 10 can be improved.

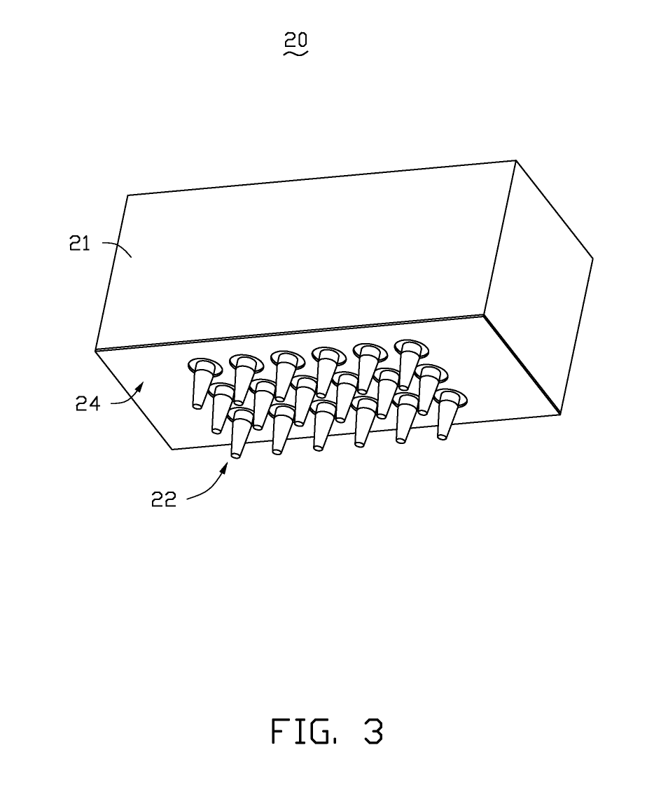

FIG. 3 illustrates a first embodiment of a processing device 20. The processing device 20 can include a main electrode 21 in the form of a rectangular block, a plurality of needle electrodes 22 inserted into the main electrode 21, and an insulating layer 24 attached to an end surface of the main electrode 21. In the illustrated embodiment, the main electrode 21 can have a particular electrical conductivity and stability.

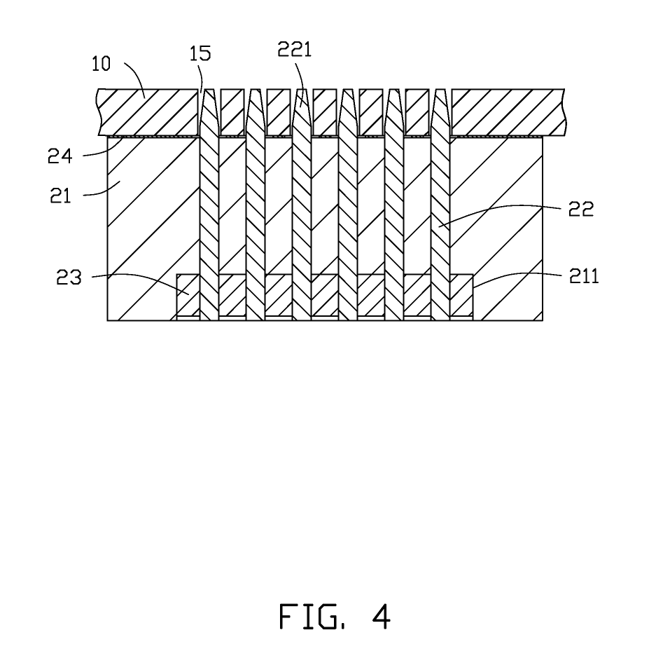

FIG. 4 illustrates that the main electrode 21 defines a recess 211. The plurality of needle electrodes 22 can be exposed beyond the main electrode 21, and received in the recess 211. The recess 211 can be filled with a solder 23, and the plurality of needle electrodes 22 can be firmly attached to the main electrode 21 by the solder 23. In the illustrated embodiment, a block of solder 23 can be melted to liquid form (liquid solder 23) beforehand, the recess 211 can be filled with the liquid solder 23, then the solder 23 can solidify through cooling. In other embodiments, the needle electrodes 22 can be firmly attached to the main electrode 21 with other methods.

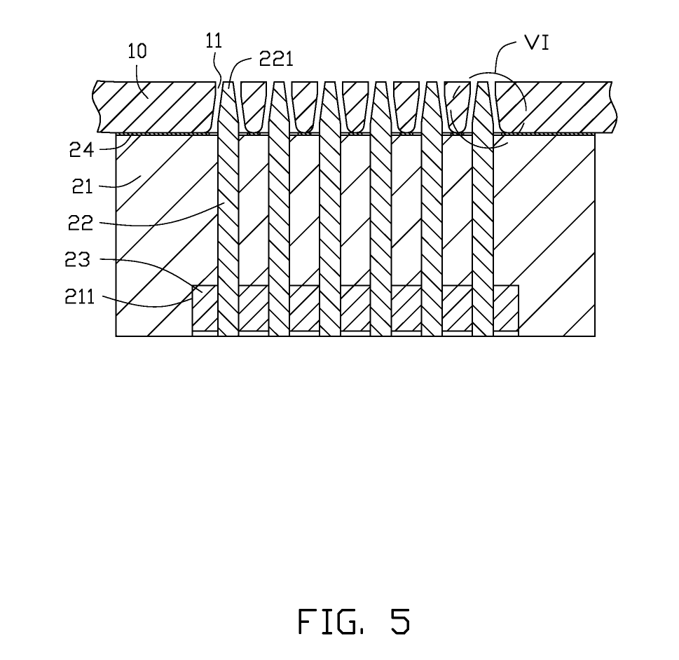

FIG. 5 illustrates that each of the plurality of needle electrodes 22 includes a processing unit 221 exposed beyond the main electrode 21.

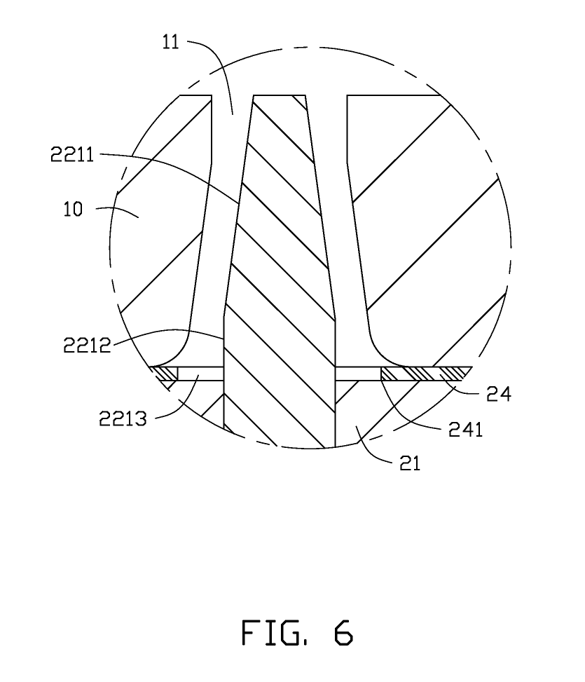

Referring to FIG. 6, the processing unit 221 can include a first portion 2211, a second portion 2212, and a third portion 2213. The first portion 2211 can be substantially conical, the second portion 2212 can be substantially cylindrical, and the second portion 2212 can be connected to the first portion 2211. The third portion 2213 can be substantially annular, and can surround and be attached to the second portion 2212. The third portion 2213 can also be attached to the main electrode 21.

An area of the main electrode 21 can be equal to an area of the insulating layer 24, and a thickness of the third portion 2213 can be equal to a thickness of the insulating layer 24. The insulating layer 24 can include a plurality of vacancies 241, and the plurality of vacancies 241 can correspond to the plurality of processing units 221. The third portion 2213 can be received in the vacancy 241, and an outer sidewall of the third portion 2213 can be tightly connected to an inner sidewall of the vacancy 241.

A processing method for the manufacture of the sound holes 11 can include following.

In step one, providing a housing 10 for electronic device with a plurality of straight holes 15 (see FIG. 4).

In step two, providing a processing device 20 with a plurality of needle electrodes 22.

In step three, the first portion 2211 and the second portion 2212 are received in a straight hole 15, and the third portion 2213 is attached to the outer surface 13 of the housing 10 (see FIG. 4).

In step four, each of the plurality of straight holes 15 is processed into a sound hole 11 by the processing device 20.

In step five, the processing device 20 is separated from the housing 10, and a process for manufacturing the housing 10 is completed.

As the diameter of the sound hole 11 increases from the inner surface 12 to the outer surface 13, sound through the sound hole 11 can have minimal loss. The processing device 20 can transform the straight hole 15 into the sound hole 11 according to an electrochemical process, avoiding any deformation.

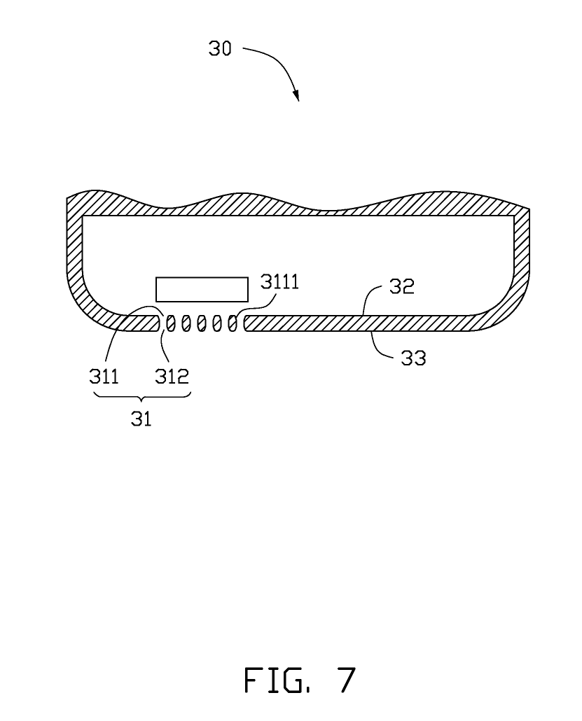

FIG. 7 illustrates a housing 30 for electronic device in a second embodiment of this disclosure. The housing 30 can include a plurality of sound holes 31, an inner surface 32, and an outer surface 33. Each sound hole 31 can include an entrance 311 and an exit 312. The housing 30 can be the same as in the first embodiment, except that a diameter of the sound hole 31 can increase from substantially a center of the sound hole 31 to the entrance 311 and the exit 312. The entrance 311 can define a rounded structure 3111, and the rounded structure 3111 can be trumpet-shaped.

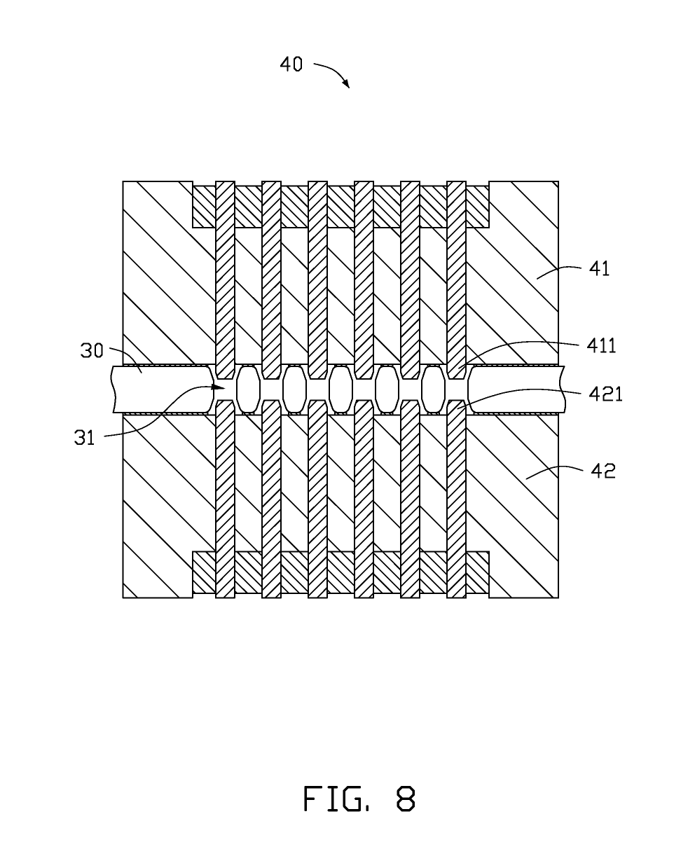

FIG. 8 illustrates a processing device 40 in a second embodiment of this disclosure. The processing device 40 can be the same as in the first embodiment, except that the processing device 40 can include a first processing device 41 and a second processing device 42. The first processing device 41 can correspond to the entrance 311, and the second processing device 42 can correspond to the exit 312. The first processing device 41 can include a first processing unit 411, the second processing device 42 can include a second processing unit 421, and a gap can be formed between the first processing unit 411 and the second processing unit 421.

The embodiments shown and described above are only examples. Many details are often found in the art such as the other features of a housing for electronic device. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A device housing for an electronic device comprising:
a plurality of sound holes defined on the housing,
an inner surface, and
an outer surface opposite to the inner surface;
wherein, each sound hole comprises an entrance located on the inner surface, and an exit located on the outer surface;
wherein, a diameter gradually increases from the center of the each sound hole to the exit.

2. The housing for an electronic device as claimed in claim 1, wherein a diameter increases from the entrance to the center of the each sound hole.

3. The housing for an electronic device as claimed in claim 1, wherein a diameter decreases from the entrance to the center of the each sound hole.

4. The housing for an electronic device as claimed in claim 1, wherein an angle of the cone of each sound hole is greater than 5 degrees and less than 40 degrees.

5. The housing for an electronic device as claimed in claim 1, wherein a diameter of the entrance is greater than 0.5 millimeters and less than 1.5 millimeters.

6. The housing for an electronic device as claimed in claim 1, wherein the exit defines a rounded structure having trumpet-shaped.

7. The housing for an electronic device as claimed in claim 1, wherein the entrance defines a rounded structure having trumpet-shaped.

8. The housing for an electronic device as claimed in claim 1, wherein the housing is made of a metal.

9. A method for manufacturing a housing for an electronic device comprising:
providing a housing with a plurality of straight holes;
providing a processing device with a plurality of needle electrodes;
wherein, a first portion and a second portion of the processing device are received in the straight hole, and a third portion of the processing device is attached to an outer surface of a housing;
wherein, each of the plurality of straight holes is processed into a sound hole by the processing device.

10. The method for manufacturing a housing for an electronic device as claimed in claim 9, wherein the processing device comprises a main electrode, and the plurality of needle electrodes are inserted into the main electrode.

11. The method for manufacturing a housing for an electronic device as claimed in claim 10, wherein an insulating layer is attached to an end surface of the main electrode, and a thickness of the insulating layer is equal to a thickness of the third portion.

12. The method for manufacturing a housing for an electronic device as claimed in claim 11, wherein the insulating layer includes a plurality of vacancies, and the third portion is received in the vacancy.

13. The method for manufacturing a housing for an electronic device as claimed in claim 10, wherein a recess is defined on the main electrode, the plurality of needle electrodes are exposed beyond the main electrode, and received in the recess.

14. The method for manufacturing a housing for an electronic device as claimed in claim 13, wherein the recess is filled with a solder, and the plurality of needle electrodes are firmly attached to the main electrode by the solder.

15. The method for manufacturing a housing for an electronic device as claimed in claim 9, wherein the first portion is conical, the second portion is cylindrical, and the third portion is annular.

16. The method for manufacturing a housing for an electronic device as claimed in claim 10, wherein the third portion is attached to the main electrode.
